(19) United States
(12) Patent Application Publication
(10) Pub. No.: US 2022/0416566 A1
(43) Pub. Date: Dec. 29, 2022

(54) BATTERY PACK WITH INTEGRATED SOLAR PANEL AND CHARGING LIGHT

(71) Applicant: Qassim Mohsin Keraib, State of Qatar (QA)

(72) Inventor: Qassim Mohsin Keraib, State of Qatar (QA)

(21) Appl. No.: 17/849,802

(22) Filed: Jun. 27, 2022

Related U.S. Application Data
(60) Provisional application No. 63/215,095, filed on Jun. 25, 2021.

(51) Int. Cl. H02J 7/35; F21S 9/03; H01M 10/44; H01M 50/204; H01M 50/296; H01M 10/0525; H01M 10/46

(52) U.S. Cl. CPC H02J 7/35; F21S 9/037; H01M 10/441; H01M 50/204; H01M 50/296; H01M 10/0525; H01M 10/465; H02J 2300/24; F21Y 2115/10

(57) ABSTRACT

A battery apparatus that includes a solar panel coupled to the battery for charging the battery and including an additional light source coupled to the battery and movable to a position to enable alternate charging of at least a portion of the battery. Accordingly, the device can generally be described as battery power source with integrated solar panel and charging light configured for placement within a housing to provide a redundant and robust power source with integrated charging capabilities.

### CROSS REFERENCE TO RELATED APPLICATIONS

This U.S. Patent Application claims priority to U.S. Provisional Patent Application No. 63/215095 filed 25 Jun. 2021 to the above-named inventor of which the disclosure is considered part of the disclosure of this application and is herein incorporated by reference in its entirety.

### FEDERALLY SPONSORED RESEARCH OR DEVELOPMENT

Not Applicable

### SEQUENCE LISTING, A TABLE, OR A COMPUTER PROGRAM

Not Applicable

### FIELD OF THE INVENTION

The invention relates generally to a battery pack with an integrated solar panel and charging light. More particularly, the invention of the present disclosure relates to a battery pack with a built-in solar panel and a light source coupled to the battery and capable of charging at least a portion of the battery through the built-in solar panel.

### BACKGROUND

With the explosion of the use of the personal electronics, the need for a power source to keep these devices charged and usable is ever present. Generally, to facilitate charging needs for these devices, an external power source is utilized. Sometimes this power source is a wall or vehicle outlet, other times, when these sources are not available, a separate power source in the form of an external battery is needed. One solution for an external battery is a standard disposable battery, but this solution fails to meet the needs of the market because they are not rechargeable. Another solution attempts to utilize rechargeable batteries, but this solution is similarly unable to meet the needs of the market because there may not be an outlet available to charge the rechargeable battery. Therefore, there is a need for an improved rechargeable power source to power these devices.

### SUMMARY OF THE INVENTION

It would be advantageous to have an apparatus that is generally described as a solar powered charging apparatus. Furthermore, it would also be advantageous to have an apparatus that is rechargeable through multiple energy sources, such as, but not limited to both artificial and natural light. Still further, it would be advantageous to have an apparatus that is portable. Therefore, there currently exists a need in the market for a battery apparatus that includes a solar panel coupled to the battery for charging the battery and includes an additional light source coupled to the battery and movable to a position to enable alternate charging of at least a portion of the battery.

The invention can generally be described as battery power source integrated solar panel and charging light according to the present disclosure and generally referred to herein as the device. The device most generally comprises a housing surrounding at least a battery. The housing being constructed out of robust and durable materials to protect the encased at least one battery from damage and harm. In a preferred assembly, this housing is comprised of a durable and resilient plastic material or carbon fiber-based material.

The at least one battery generally comprising a power source in the form of a rechargeable battery, preferably of the lithium-ion type, although other known battery chemistries and battery types may be utilized without departing from the spirit of the invention. To provide sufficient power and capabilities it is anticipated that the at least one battery is comprised of a plurality of batteries or battery cells to form a battery system with sufficient power for use in a multitude of applications and uses.

The housing including a solar cell. The solar cell preferably integrated directly into the housing. The solar cell size may be placed in multiple positions and sides on the housing, but is preferably integrated into the largest portion of the housing and encompasses a majority of this largest portion to provide increased light capture. The solar cell preferably being a plurality of photovoltaic cells coupled together to form a cohesive solar cell or as it may alternately be referred, a solar panel. The solar cell of the device generally configured to convert light (both artificial and sunlight) to electricity through the photovoltaic effect. Accordingly, the solar cell is coupled to the at least one battery to provide electrical energy to the at least one battery for the purpose charging the at least one battery when needed or desired.

The housing further including a light source. The light source preferably comprised of a plurality of light emitting diodes (LED) or incandescent bulbs to generate light waves for illumination and interaction with the solar cell. The light source generally movably affixed to the housing, wherein the light source can be moved to a plurality of positions including, but not limited to, a first position and a second position. The second position of the light source generally allowing the light source to be utilized for illuminating a surrounding area of the device, similar to a flashlight and additionally uncovering the solar cell for access to sunlight or another light source the for device at least one battery charging purposes.

The first position of the light source positioned in direct adjacency to the solar cell with the diodes or bulbs in direct alignment with a working portion of the solar cell, wherein the diodes or bulbs of the light source are configured to operate the solar cell to generate an electrical current. This electrical current of the solar cell can then be utilized by the at least one battery to either 1) continue to the power the light source; 2) provide power to an attached device through a connector, such as, but not limited to a cable; and 3) charge the at least one battery. Accordingly, the device generally provides a redundant feedback loop for operation of the device. The light source further including a attachment securing means to secure the light source in the first position directly adjacent to the solar cell. Accordingly, the light source first position and securing means securing the light source into position for charging and also protecting the solar cell from damage by covering the entirety of the solar cell in a secured position.

In an alternate expression of the light source, the light source can be described as functioning as a protective cover for the solar cell within the housing, wherein the light source is movable to expose the solar cell for charging and additionally allow for use of the light source for illumination purposes.

The device may be utilized as a battery for a charging source, wherein the technological features of the device are generally increased in scale and capacity for use in charging purposes. The device size and features are capable of use in a variety of circumstances and devices, wherein the device integrated solar cell, light source, and at least one battery adjacent and movable configuration can be integrated into multiple battery platforms and uses to save, conserve, and generally better manage power generation and storage.

The invention now will be described more fully hereinafter with reference to the accompanying drawings, which are intended to be read in conjunction with both this summary, the detailed description and any preferred and/or particular embodiments specifically discussed or otherwise disclosed. This invention may, however, be embodied in many different forms and should not be construed as limited to the embodiments set forth herein; rather, these embodiments are provided by way of illustration only and so that this disclosure will be thorough, complete and will fully convey the full scope of the invention to those skilled in the art.

### BRIEF DESCRIPTION OF THE DRAWINGS

FIG. 1 shows a perspective view of a first embodiment of the battery pack having a solar cell and charging light device, according to the present disclosure;

FIG. 2 shows an upper perspective view of the first embodiment, according to the present disclosure;

FIG. 3 shows a lower perspective view of the first embodiment, according to the present disclosure;

FIG. 4 shows an additional view of the device, according to the present disclosure; and

FIG. 5 shows a view of an alternate embodiment of the device, according to the present disclosure.

### DETAILED DESCRIPTION OF THE INVENTION

The following detailed description includes references to the accompanying drawings, which forms a part of the detailed description. The drawings show, by way of illustration, specific embodiments in which the invention may be practiced. These embodiments, which are also referred to herein as “examples,” are described in enough detail to enable those skilled in the art to practice the invention. The embodiments may be combined, other embodiments may be utilized, or structural, and logical changes may be made without departing from the scope of the present invention. The following detailed description is, therefore, not to be taken in a limiting sense.

Before the present invention of this disclosure is described in such detail, however, it is to be understood that this invention is not limited to particular variations set forth and may, of course, vary. Various changes may be made to the invention described and equivalents may be substituted without departing from the true spirit and scope of the invention. In addition, many modifications may be made to adapt a particular situation, material, composition of matter, process, process act(s) or step(s), to the objective(s), spirit, or scope of the present invention. All such modifications are intended to be within the scope of the disclosure made herein.

Unless otherwise indicated, the words and phrases presented in this document have their ordinary meanings to one of skill in the art. Such ordinary meanings can be obtained by reference to their use in the art and by reference to general and scientific dictionaries.

References in the specification to “one embodiment” indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The following explanations of certain terms are meant to be illustrative rather than exhaustive. These terms have their ordinary meanings given by usage in the art and in addition include the following explanations.

As used herein, the term “and/or” refers to any one of the items, any combination of the items, or all of the items with which this term is associated.

As used herein, the singular forms “a,” “an,” and “the” include plural reference unless the context clearly dictates otherwise.

As used herein, the terms “include,” “for example,” “such as,” and the like are used illustratively and are not intended to limit the present invention.

As used herein, the terms “preferred” and “preferably” refer to embodiments of the invention that may afford certain benefits, under certain circumstances. However, other embodiments may also be preferred, under the same or other circumstances.

Furthermore, the recitation of one or more preferred embodiments does not imply that other embodiments are not useful and is not intended to exclude other embodiments from the scope of the invention.

As used herein, the terms “front,” “back,” “rear,” “upper,” “lower,” “right,” and “left” in this description are merely used to identify the various elements as they are oriented in the FIGS, with “front,” “back,” and “rear” being relative to the apparatus. These terms are not meant to limit the elements that they describe, as the various elements may be oriented differently in various applications.

As used herein, the term “coupled” means the joining of two members directly or indirectly to one another. Such joining may be stationary in nature or movable in nature. Such joining may be achieved with the two members, or the two members and any additional intermediate members being integrally formed as a single unitary body with one another or with the two members or the two members and any additional intermediate members being attached to one another. Such joining may be permanent in nature or alternatively may be removable or releasable in nature. Similarly, coupled can refer to a two member or elements being in communicatively coupled, wherein the two elements may be electronically, through various means, such as a metallic wire, wireless network, optical fiber, or other medium and methods.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure.

Following are more detailed descriptions of various concepts related to, and embodiments of, methods and apparatus according to the present disclosure. It should be appreciated that various aspects of the subject matter introduced above and discussed in greater detail below may be implemented in any of numerous ways, as the subject matter is not limited to any particular manner of implementation. Examples of specific implementations and applications are provided primarily for illustrative purposes.

The invention can generally be described as battery power source that includes a solar panel coupled to the battery and including a light capable of positioning in an adjacent position relative to the solar panel for charging at least a portion of the battery through the solar cell. In a first embodiment of the device, the device is generally utilized as a portable power source. In alternate embodiments of the device, the device charging and light features can be integrated directly into a larger battery or battery systems for uses, including, but not limited to, fixed batteries within electric vehicles or electric vehicle charging stations.

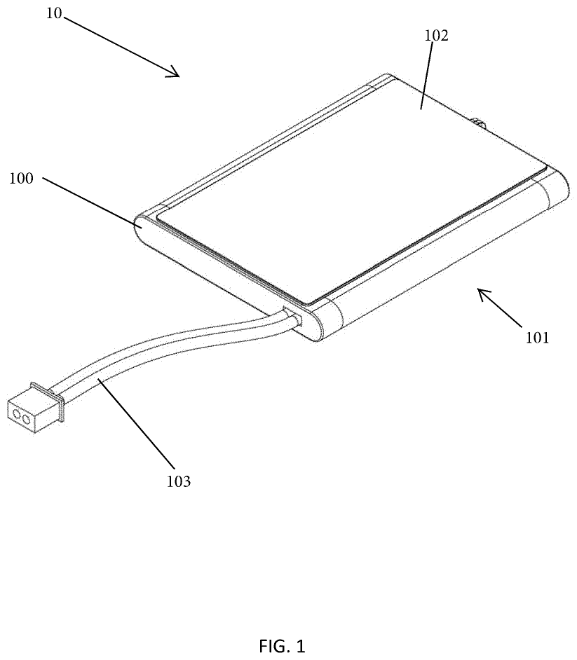

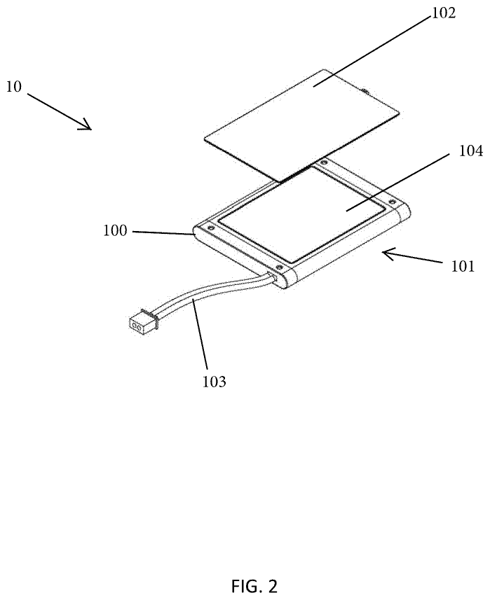

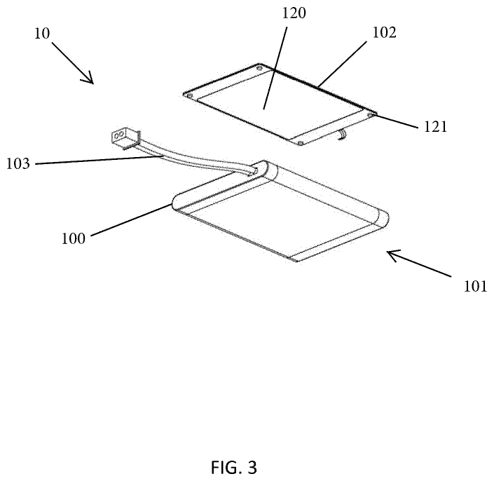

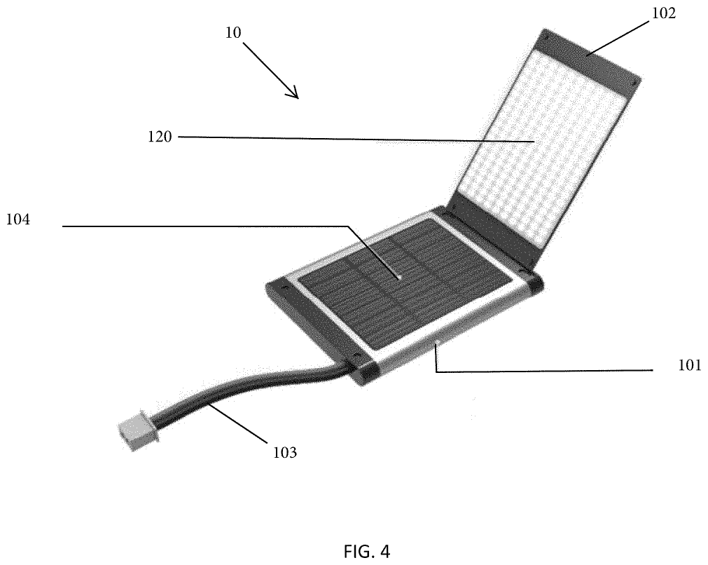

Referring to the figures, FIG. 1 to FIG. 5 shows a battery pack with integrated solar panel and charging light according to the present disclosure and generally referred to herein as device 10. The device 10 most generally comprises a housing 100 surrounding at least a battery 101. The housing being constructed out of robust and durable materials to protect the encased at least one battery 101 from damage and harm. In a preferred assembly, this housing is comprised of a durable and resilient plastic material or carbon fiber-based material.

The at least one battery 101 generally comprising a power source in the form of a rechargeable battery, preferably of the lithium-ion type, although other known battery chemistries and battery types may be utilized without departing from the spirit of the invention. To provide sufficient power and capabilities it is anticipated that the at least one battery 101 is comprised of a plurality of batteries 101 or battery cells to form a battery system with sufficient power for use in a multitude of applications and uses.

The housing 100 including a solar cell 104. The solar cell 104 preferably integrated directly into the housing 100. The solar cell 104 size may be placed in multiple positions and sides on the housing 100, but is preferably integrated into the largest portion of the housing and encompasses a majority of this largest portion to provide increased light capture. The solar cell 104 preferably being a plurality of photovoltaic cells coupled together to form a cohesive solar cell 104 or as it may alternately be referred, a solar panel 104. The solar cell 104 of the device 10 generally configured to convert light (both artificial and sunlight) to electricity through the photovoltaic effect. Accordingly, the solar cell 104 is coupled to the at least one battery 101 to provide electrical energy to the at least one battery 101 for the purpose charging the at least one battery 101 when needed or desired.

The housing 100 further including a light source 102. The light source 102 preferably comprised of a plurality of light emitting diodes (LED) or incandescent bulbs 120 to generate light waves for illumination and interaction with the solar cell 104. The light source 102 generally movably affixed to the housing 100, wherein the light source 102 can be moved to a plurality of positions including, but not limited to, a first position and a second position. The second position of the light source 102 generally allowing the light source 102 to be utilized for illuminating a surrounding area of the device 10, similar to a flashlight and additionally uncovering the solar cell 104 for access to sunlight or another light source the for device 10 at least one battery 101 charging purposes.

The first position of the light source 102 positioned in direct adjacency to the solar cell 104 with the diodes or bulbs 120 in direct alignment with a working portion of the solar cell 104, wherein the diodes or bulbs 120 of the light source 102 are configured to operate the solar cell 104 to generate an electrical current. This electrical current of the solar cell 104 can then be utilized by the at least one battery 101 to either 1) continue to the power the light source 102; 2) provide power to an attached device through a connector, such as, but not limited to a cable 103; and 3) charge the at least one battery 101. Accordingly, the device 10 generally provides a redundant feedback loop for operation of the device 10. The light source 102 further including an attachment securing means 121 to secure the light source 102 in the first position directly adjacent to the solar cell 104. Accordingly, the light source 102 first position and securing means 121 securing the light source 102 into position for charging and also protecting the solar cell 104 from damage by covering the entirety of the solar cell 104 in a secured position.

In an alternate expression of the light source 102, the light source 102 can be described as functioning as a protective cover for the solar cell 104 within the housing 100, wherein the light source 102 is movable to expose the solar cell 104 for charging and additionally allow for use of the light source 102 for illumination purposes.

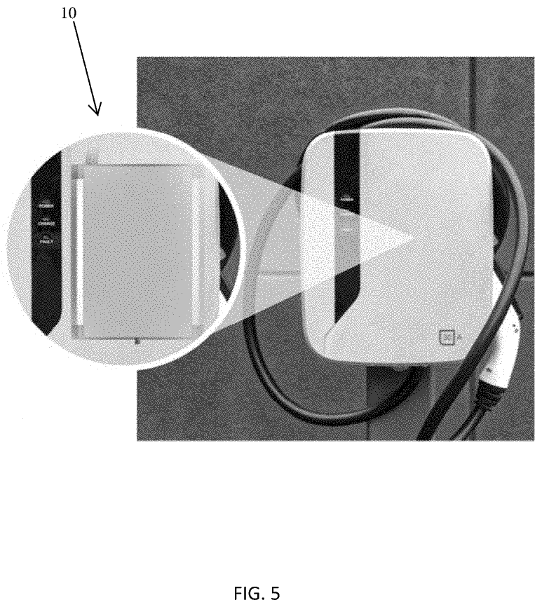

Referring now specifically to FIG. 5, an alternate embodiment of the device 10 is generally illustrated as being integrated within a charging device for a vehicle. Accordingly, the device 10 may be utilized as a battery for a charging source, wherein the technological features of the device 10 are generally increased in scale and capacity for use in charging purposes. The device 10 size and features are capable of use in a variety of circumstances and devices, wherein the device 10 integrated solar cell 104, light source 102, and at least one battery 101 adjacent and movable configuration can be integrated into multiple battery platforms and uses to save, conserve, and generally better manage power generation and storage. The device 10 is most generally described as being rechargeable, solar powered, and portable and providing a robust solution for the use of artificial and natural light in the charging of a portable power source.

While the invention has been described above in terms of specific embodiments, it is to be understood that the invention is not limited to these disclosed embodiments. Upon reading the teachings of this disclosure many modifications and other embodiments of the invention will come to mind of those skilled in the art to which this invention pertains, and which are intended to be and are covered by both this disclosure and the appended claims. It is indeed intended that the scope of the invention should be determined by proper interpretation and construction of the appended claims and their legal equivalents, as understood by those of skill in the art relying upon the disclosure in this specification and the attached drawings.

What is claimed is:

1. A power source with integrated charging apparatus, the power source comprising:
a housing; the housing generally surrounding the power source and comprising:
at least one battery;
a solar cell; the solar cell coupled to the at least one battery, wherein the solar cell can charge the at least one battery; and
a light source, the light source coupled to the at least one battery and movable to a position adjacent the solar cell, wherein the light source is capable of illuminating the solar cell for at least one battery charging purposes; and
a cord; the cord coupled to the at least battery through the housing, wherein the cord enables attachment of the at least one battery to a device for charging and recharging purposes.

2. The power source as in claim 1, wherein the at least one battery is comprised of multiple cells with the multiple cells coupled to the solar cell.

3. The power source as in claim 1, wherein the light source is a light emitting diode.

4. The power source as in claim 1, wherein the solar cell is a solar panel comprised of multiple solar cells.

5. The power source as in claim 1, wherein the light source is configured as a cover for the solar cell.

6. A portable battery operated power source with integrated charging apparatus, the portable battery operated power source comprising:
a housing; the housing generally surrounding the portable power source and comprising:
at least one battery;
a solar cell; the solar cell coupled to the at least one battery, wherein the solar cell can charge the at least one battery; and
a light source, the light source coupled to the at least one battery and movable between a first position directly adjacent the solar cell and a second position, wherein the light source is capable of illuminating the solar cell for at least one battery charging purposes; and
a cord; the cord coupled to the at least battery through the housing, wherein the cord enables attachment of the at least one battery to a device for charging and recharging purposes.

7. The portable power source as in claim 6, wherein the at least one battery is comprised of multiple cells with the multiple cells coupled to the solar cell.

8. The portable power source as in claim 6, wherein the light source is a light emitting diode.

9. The portable power source as in claim 6, wherein the solar cell is a solar panel comprised of multiple solar cells.

10. The power source as in claim 6, wherein the light source is configured as a cover for the solar cell and movable between the first position and the second position.

11. A power source with redundant charging, the power source comprising:
at least one battery;
a housing; the housing generally surrounding the at least one battery;
a solar cell; the solar cell coupled to the at least one battery and positioned on an exterior of the housing, wherein the solar cell can charge at least a portion of the at least one battery;
a light source, the light source coupled to the at least one battery and movable between a first position directly adjacent the solar cell and a second position, wherein the light source is capable of illuminating the solar cell for at least one battery charging purposes; and
a cord; the cord coupled to the at least battery through the housing, wherein the cord enables attachment of the at least one battery to an additional device for charging and recharging purposes.

12. The power source as in claim 11, wherein the at least one battery is comprised of multiple cells with the multiple cells coupled to the solar cell.

13. The power source as in claim 11, wherein the at least one battery is of the lithium-ion type.

14. The power source as in claim 11, wherein the light source is a light emitting diode.

15. The power source as in claim 11, wherein the solar cell is a solar panel comprised of multiple solar cells.

16. The power source as in claim 11, wherein the light source is configured as a cover for the solar cell and movable between the first position and the second position.

17. The power source as in claim 16, wherein the light source includes a securing means, the securing means configured to secure the light source to the housing in the first position adjacent the solar cell.
